(19) United States
(12) Patent Application Publication
(10) Pub. No.: US 2026/0150235 A1
(43) Pub. Date: May 28, 2026

(54) DISTRIBUTING COOLANT

(71) Applicant: Teradyne, Inc., North Reading, MA (US)

(72) Inventors: Alexander I. Yatskov, Manteca, CA (US); Kevin A. Thompson, Thousand Oaks, CA (US); Michael G. Herzog, Grayslake, IL (US)

(73) Assignee: Teradyne, Inc., North Reading, MA (US)

(21) Appl. No.: 18/957,443

(22) Filed: Nov. 22, 2024

(51) Int. Cl. H05K 7/20

(52) U.S. Cl. CPC H05K 7/20272; H05K 7/20772

(57) ABSTRACT

An example system includes a structure that includes a slot; a carrier that includes a surface arranged to receive a flow of coolant, where the carrier includes holes to allow coolant to pass therethrough, where the holes are on a part of the carrier other than the surface, and where at least part of the carrier, including the surface, is within the slot; and a stiffness adjuster between a part of the carrier and a part of the structure, where the stiffness adjuster has a stiffness that is based on a target impedance of coolant flow through the slot.

### TECHNICAL FIELD

This specification describes example implementations of systems and processes for distributing coolant in a system, such as a test system.

### BACKGROUND

Electronic devices generate heat during operation. Excessive heat can damage an electronic device, adversely affecting operation of the device or making the device inoperable. Coolant flow may be used to cool electronic devices during their operation.

By way of example, an enclosure may house multiple circuit boards, which qualify as electronic devices for the purpose of systems and processes described herein. When an enclosure contains open channels, as may be the case for one that houses circuit boards, coolant movers quite often are not capable of intelligent coolant distribution. Coolants, particularly gaseous coolants, tend to follow the path of least resistance, which often does not match with where the coolant is needed. Such coolant streams, which may be of little utility from a cooling perspective, are typically called side passes, overpasses, or underpasses.

### SUMMARY

An example system includes a structure that includes a slot; a carrier that includes a surface arranged to receive a flow of coolant, where the carrier includes holes to allow coolant to pass therethrough, where the holes are on a part of the carrier other than the surface, and where at least part of the carrier, including the surface, is within the slot; and a stiffness adjuster between a part of the carrier and a part of the structure, where the stiffness adjuster has a stiffness that is based on a target impedance of coolant flow through the slot. The example system may include one or more of the following features, either alone or in combination.

At least one of a size, a shape, a number, or locations of the holes may be based on the target impedance of the flow of coolant through the slot.

The system may include an enclosure containing the structure. The enclosure may include a coolant inlet and a coolant outlet that together enable a coolant flow path through the enclosure. The carrier may be arranged in the coolant flow path such that the flow of coolant extends to and through the holes of the carrier.

The stiffness adjuster may include a spring. The carrier may be mounted such that force resulting from the flow of coolant at the surface of the carrier causes the carrier to move within the slot. An amount of movement of the carrier within the slot may be based on the stiffness of the spring.

The system may include multiple springs between respective parts of the carrier and respective parts of the structure, where the spring is among the multiple springs. The multiple springs may have stiffnesses that are based on the target impedance of the flow of coolant through the slot.

The carrier may include multiple surfaces including the surface. Each of the multiple surfaces may have having a respective set of sides extending therefrom. Each respective set of sides may include holes to allow coolant to pass therethrough. The slot may include multiple openings. Each opening may hold a corresponding surface of the carrier. The force resulting from the flow of coolant at surfaces of the carrier may cause the carrier to move within the slot. An amount of movement of the carrier within the slot may be based on the stiffnesses of the multiple springs.

The system may include an electrical connector associated with the slot. The electrical connector may be configured to hold an electronic device to be tested.

The enclosure may include one or more coolant movers to produce the coolant flow. The one or more coolant movers may be or include one or more fans located at or near the coolant outlet of the enclosure.

The structure may include multiple slots. The system may include multiple carriers including the carrier. Each respective carrier of the multiple carriers may include a respective surface comprising holes to allow a respective flow of coolant to pass therethrough. At least part of each respective carrier may include a respective surface thereof being within a respective slot of the multiple slots. The stiffness adjuster may include a spring and the system may include multiple springs including the spring. Each of the multiple springs may be between a part of a respective carrier and a part of the structure. Each spring may have a stiffness that is based on a target impedance of the flow of coolant through the respective slot.

Different ones of the multiple slots may have different target impedances for the flow of coolant. The stiffness of each spring may be configured so that differences between flows of coolant through the multiple slots are reduced. The system may include electrical connectors associated respective slots of the multiple slots. Each electrical connector may be for holding an electronic device to be tested. The system may include test electronics to test the electronic device in each slot.

An example system includes multiple carriers, each of which includes holes to allow coolant to pass therethrough; a frame that includes multiple slots, each of which includes openings for holding a respective one of the multiple carriers such that the respective one of the multiple carriers is movable within the slot; and springs between each of the multiple carriers and the frame, with each spring having a stiffness that affects movement of a respective carrier within a respective slot in response to coolant flow contacting the respective carrier. Each spring is arranged relative to the frame and the multiple carriers so that differences between coolant flow through the multiple slots are reduced. The example system may include one or more of the following features, either alone or in combination.

The system may include electrical connectors associated with respective slots. Each electrical connector may be for holding an electronic device to be tested within a coolant flow path. At least one of a size, a shape, a number, or locations of the holes in each carrier is based on the target impedance of coolant flow through each slot. Each carrier may have a rectangular shape in cross-section with one end of the rectangular shape open. The system may be part of/included in automatic test equipment.

Any two or more of the features described in this specification, including in this summary section, may be combined to form implementations not specifically described in this specification.

At least part of the devices, systems, and processes described in this specification may be configured or controlled by executing, on one or more processing devices, instructions that are stored on one or more non-transitory machine-readable storage media. Examples of non-transitory machine-readable storage media include read-only memory, an optical disk drive, memory disk drive, and random access memory. At least part of the devices, systems, and processes described in this specification may be configured or controlled using a computing system comprised of one or more processing devices and memory storing instructions that are executable by the one or more processing devices to perform various control operations. The devices, systems, and processes described in this specification may be configured, for example, through design, construction, composition, arrangement, placement, programming, operation, activation, deactivation, and/or control.

The details of one or more implementations are set forth in the accompanying drawings and the following description. Other features and advantages will be apparent from the description and drawings, and from the claims.

### DESCRIPTION OF THE DRAWINGS

FIG. 1 is perspective view of an example enclosure that is part of an example test system and that is configured to test electronic devices.

FIG. 2 is a perspective view of an example frame included in the enclosure and an example carrier to control distribution of air flow through the enclosure.

FIG. 3 is a cut-away perspective view of part of the example carrier.

FIG. 4 is a perspective view of part of the example carrier.

FIG. 5 is a perspective view of part of the example carrier.

FIG. 6 is a perspective view of an example frame and the example carrier.

FIG. 7 is a block diagram of example components of an example test system that includes the enclosure of FIG. 1.

Like reference numerals in different figures indicate like elements.

### DETAILED DESCRIPTION

Described herein are examples of systems and processes for distributing coolant in a system containing electronic devices. In this context, an electronic device includes, but is not limited to, individual components such as a microchip, an integrated circuit (IC), or a silicon chip, or an assembly such as a printed circuit board (PCB) containing multiple passive and/or active electronic components such as those listed.

The example systems and processes are described in the context of a test system. A test system is configured to test the operation of an electronic device. An electronic device tested by a test system is referred to as a device under test (DUT). The systems and processes, however, are not limited to use with a test system and may be used in any system that holds heat-generating devices such as, but not limited to, a computing system, a blade server, or the like. The systems and processes are not limited to use with electronic devices, but rather may be used to cool any type of device that generates heat, such as motors or automotive parts.

The systems and processes described herein operate on the premise that coolant should be properly distributed, e.g., more coolant to hot areas of a test system and less coolant to cold areas of the test system. The systems and processes operate on the further premise that open sockets of the test system, which may be less hot than non-open slots, are already cooler than non-open slots and, therefore, may require less coolant than non-open slots. In the non-open slots, which may be called “hot slots” because they are populated with heated components, the systems and processes allow more coolant to move through those slots using the mechanical mechanisms described below, such as springs and holes in a carrier. The systems and processes are configured to enable coolant in colder areas of the test system to be redistributed to hotter areas of the test system where the coolant is needed more. The systems and processes thus may implement a mechanical adaptive control system for the distribution of coolant, examples of which are described below.

The example systems and processes are described below using air flow as the coolant. However, in some implementations, the coolant may be a substance other than air. For example, the coolant may be a gas such as, but not limited to, carbon dioxide, freon, argon, helium, and/or nitrogen. For example, the coolant may be a liquid such as, but not limited to, water, ethylene glycol, propylene glycol, mineral oil, and/or dielectric fluids. The type of coolant used may be dictated, at least in part, by the type of device being cooled. For example, gases may be more appropriate than liquids for cooling electronic devices. The cooling that occurs may be or include two-phase cooling. Two phase cooling may include the transfer of heat by the evaporation and condensation of a portion or all of a liquid coolant, such as those listed above.

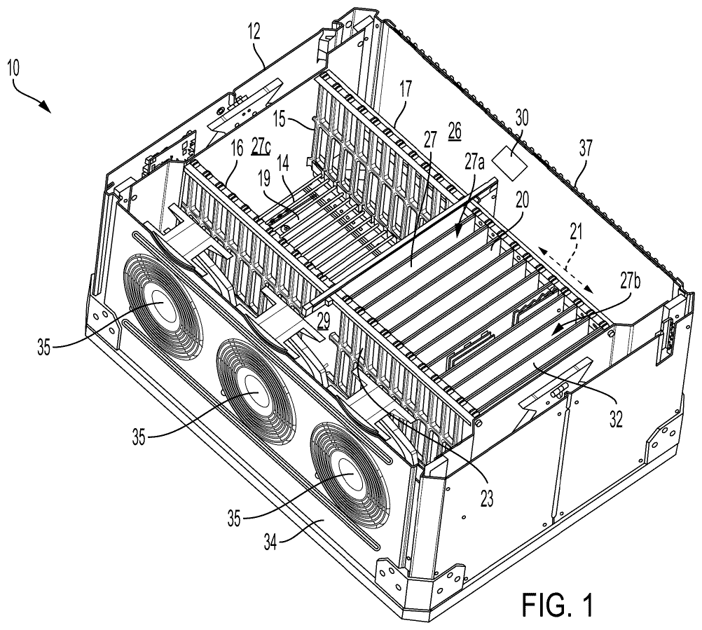

FIG. 1 shows an example component of a test system 10 that holds multiple electronic devices for testing. In this example, the electronic devices are circuit boards, such as PCBs. An example PCB is a hardware device that may include one or more of the following: memory, one or more processing devices such as those described herein, passive electronic devices such as capacitors and resistors, and/or active electronic devices such as those listed above, waveform generators, digital-to-analog converters, analog-to-digital converters, transducers, wireless transmitters, or the like.

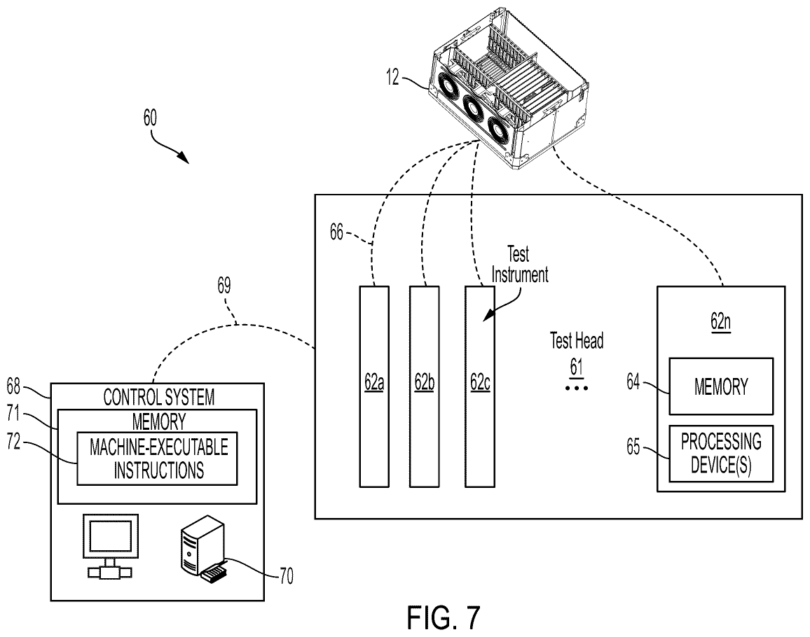

The test system includes enclosure 12. Enclosure 12 includes sockets 14 containing electrical connectors configured to receive PCBs (that is, DUTs) to be tested. Each electrical connector mates to a complementary electrical connector on a PCB to enable electrical signals to pass over the mated electrical connectors to and/or from the PCB. Test system 10 may include one or more test instruments (see, e.g., FIG. 7) to send and/or to receive the electrical signals from the PCBs. A test instrument may be a hardware devices that may include one or more processing devices and/or other circuitry. The test instrument may be configured—for example, programmed—to output commands to test PCBs in the sockets. The commands to test the PCBs may be or include instructions, signals, data, parameters, variables, test patterns, and/or any other information designed to elicit response(s) from a PCB.

In this example, the sockets are bounded by structures, such as a frames 15 and 16, each of which may include multiple slots 17. Each frame 15, 16 may be at an angle, such as 90°±15°, relative to surface 19 containing the sockets. Slots in frame 15 may align, or substantially align (e.g., to within single-digit millimeters), to slots in frame 16.

Each slot in frame 15 and frame 16 is associated with a corresponding socket and, ultimately, with a PCB in that socket. For example, slots in frames 15 and 16 may align, or substantially align to respective sockets and to PCBs when PCBs are in the sockets. In the example of FIG. 1, PCB 20 aligns to a corresponding slot 23 in frame 16 and to a corresponding slot (not visible) in frame 15. The other PCBs and slots may be similarly aligned. In some implementations, the slots in frames 15 and 16 may be offset to the left or right (e.g., in a direction of arrow 21) of each socket and any PCB in each respective socket. In some implementations, the width 22 (measured parallel to line 21) of each slot is the same as, or greater than, the width of a PCB (also measured parallel to line 21) that fits into a corresponding socket. This configuration may assist in air flow, since it may allow may to flow over both surfaces of the PCB.

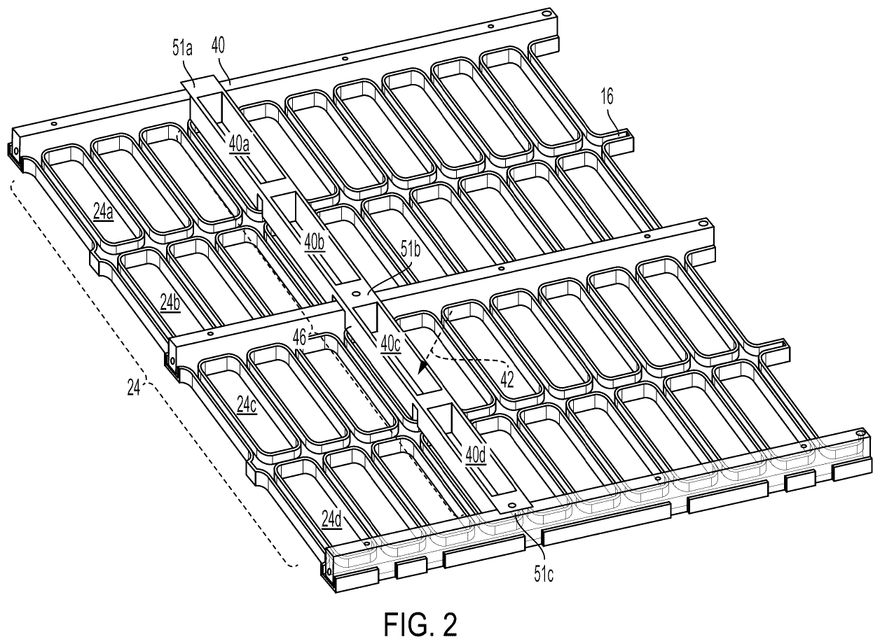

Referring to FIG. 2, each slot, such as slot 24, of a frame such as frame 16, may contain one or more openings. An opening is a synonym for a hole, but “opening” is used here to distinguish the slot openings from the carrier holes described herein. In the example of FIG. 2, there are four openings (e.g., 24a, 24b, 24c, 24d) per slot, but a single slot may contain a single opening, two openings, three openings, five openings, six openings, and so forth. In this example, referring back to FIG. 1, the openings are part of an air flow path from region 26 to region 27 to region 29 of enclosure 12. In this example, either ambient or temperature-controlled air (e.g., cooled/below room temperature air, which may be below 20 to 22° C. (68 to 72° F.)) enters region 26 at one or more air inlets 30 of enclosure 12 and is expelled through region 29 of enclosure 12. In this example, the air flow path thus extends from region 26 through the openings in frame 15, over region 27 of enclosure 12 containing sockets and PCBs, through the openings in frame 16 to region 29, and thereafter out of enclosure 12. The air flow cools, or is intended to cool, PCBs 32 before, during, and/or after operation. Operation in this context may include testing the PCBs by the test system.

The alignment of the openings with the slots/PCBs and the width of the openings may be selected to ensure appropriate volumes of air pass over the PCBs to implement the levels of cooling desired during testing.

Enclosure 12 also includes coolant movers. In the case where air or other gas is the coolant, the coolant movers may be blowers or fans. In other implementations where liquid is used as the coolant, the coolant movers may be pumps to pump liquid coolant. In the example of enclosure 12, air movers, such as blowers or fans, are located at wall 34 of enclosure 12. In this example, three fans 35 are used as air movers; however, enclosure 12 may contain fewer than three fans (e.g., one or two fans) or more than three fans (e.g., four, five, six, and so forth fans). In this example, fans 35 are placed adjacent to region 29 to suction air along the air flow path. That is, suction created by operation of fans 35 suctions air into region 26 from outside of enclosure 12 via air inlet(s) 30 on wall 37, from region 26 through openings in frame 15 over and through region 27 containing sockets and PCBs, through openings in frame 16 to region 29 and from region 29 to an exterior of enclosure 12.

In some implementations, the air movers (e.g., fans) may be located at wall 37 of enclosure 12 (and not at wall 34 of enclosure 12) and air outlets (not shown) may be located at wall 35 of enclosure 23. In this example, the air movers force air along the air flow path. That is, air movement created by operation of the fans blows air from region 26 through openings in frame 15, over region 27 of enclosure 12 containing sockets and PCBs, through openings in frame 16 to region 29, and from region 29 to an exterior of enclosure 12 via the air outlets.

Referring also to FIG. 2, at least part of a carrier, such as carrier 40, may be arranged in one or more slots of frames 15 and/or 16. For example, an instance of the carrier 40 may be arranged in all slots of each frame 15 and 16. For example, an instance of the carrier may be arranged in all slots of frame 15 only. For example, an instance of the carrier may be arranged in all slots of frame 16 only. For example, an instance of the carrier may be arranged in some, but not all, slots of frame 15. For example, an instance of the carrier may be arranged in some, but not all, slots of frame 16. In examples where an instance of the carrier is arranged in some, but not all slots, the carrier(s) may be strategically positioned to account for variations in the volume of air flow in different parts of the enclosure. For example, if the air flow is greater at a center of region 27 of enclosure 12, the carriers may be arranged in slots at or near the center region to reduce air flow in that region.

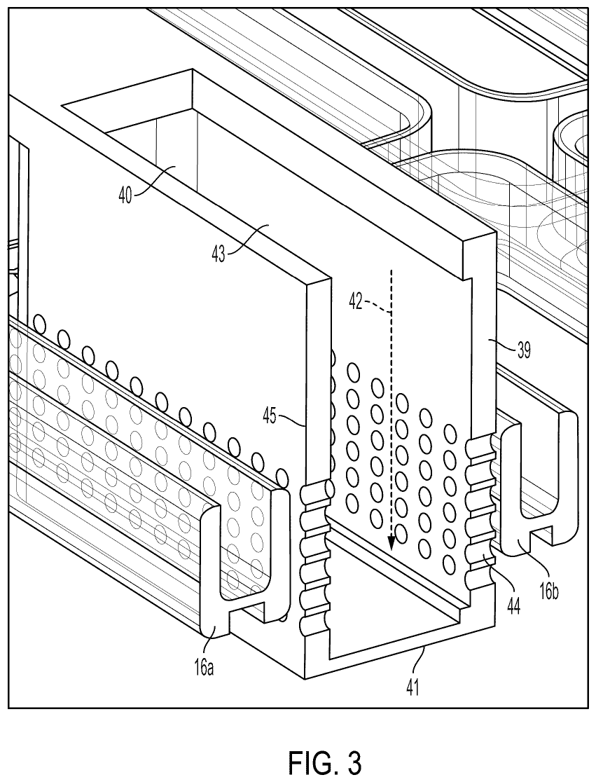

Referring to FIGS. 2 and 3, example carrier 40 includes a surface 41 configured to receive at least part a flow of air. In the example of FIG. 3, surface 41 is flat; however, this is not a requirement. The surface may be semi-circular or have grooves or any appropriate shape. In this example, surface 41 does not include holes. As a result, air pressure at surface 41, resulting from at least part of the flow of air described herein, forces movement of carrier 41 in the direction 42 of the air flow. Thus, the open end 43 of carrier 40 faces the direction of air flow through enclosure 12. In this example, the cross-section of the carrier is rectangular in shape; however, other implementations may have different cross-sectional shapes, e.g., square, triangular, elliptical, or the like.

Carrier 40 includes holes 44, through which air can pass. The holes may be on a part of carrier 40 other than surface 41. In the examples of FIGS. 2 and 3, the holes are on sides 45, 39 of the carrier. In this example, there are six holes on each side of the carrier; however, there may be fewer than six holes per side (e.g., one, two, three, and so forth holes) or more than six holes per side (e.g., seven, eight, nine, and so forth holes). In some implementations, the holes may be on only one side, such as side 45 or side 39. In this example, the holes are round in shape; however, other shapes, such as oval holes, rectangular holes, or square holes may be used.

One or more of a size, a shape, a number, or locations of the holes may be based on a target impedance of the flow or air through the slot. Impedance of air flow includes a resistance to air flow through the slot.

In some implementations, a carrier may include multiple sides/surface combinations of the type shown in FIG. 3—one for each opening of the slot. For example, as shown in FIG. 2, example carrier 40 includes four sides/surface combinations 40a, 40b, 40c, and 40d, each of which is configured to fit within a corresponding opening in a slot 46 of frame 16. That is, each of 40a, 40b, 40c, and 40d may have the cross-sectional configuration and function shown in FIG. 3.

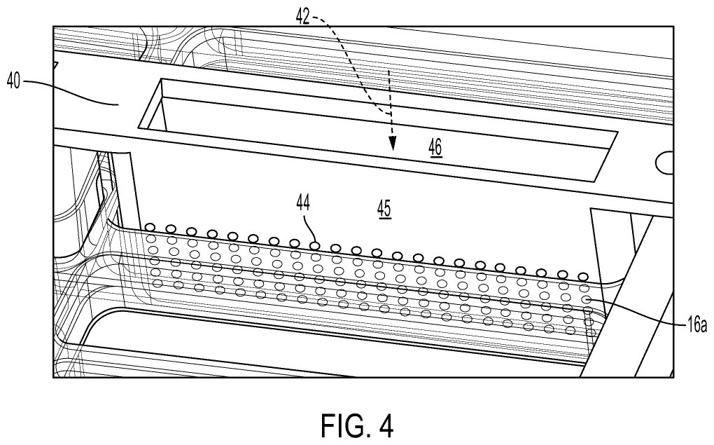

As shown in FIGS. 3 and 4, carrier 40 may be installed within openings of frame 16 such that, absent force such as the flow of air impacting the carrier, sides 16a, 16b of frame 16 cover, and therefore block, all or the majority of each corresponding carrier's holes 44. The sides of the carrier are shown as transparent to illustrate holes 44 but, in fact, are not transparent in some implementations. Carrier 40 is mounted to the frame so that the carrier is movable within the slot in the direction of the flow of air created by the air mover(s), e.g., in the direction of arrow 42.

Referring to FIGS. 2, 5, and 6, in some implementations, each carrier such as carrier 40 is coupled to a frame such as frame 16 using one or more stiffness adjusters arranged between a part of the carrier and a part of the frame. The stiffness adjuster(s) may have a stiffness that is based, at least in part, on a target impedance of air flow through the slot in which the carrier is installed. For example, if the target impedance is generally large, the stiffness adjusters may have a greater stiffness, whereas if the target impedance is generally small, the stiffness adjusters may have a lower stiffness.

In some implementations, different slots may have different target impedances. In some implementations, all slots may have the same target impedance.

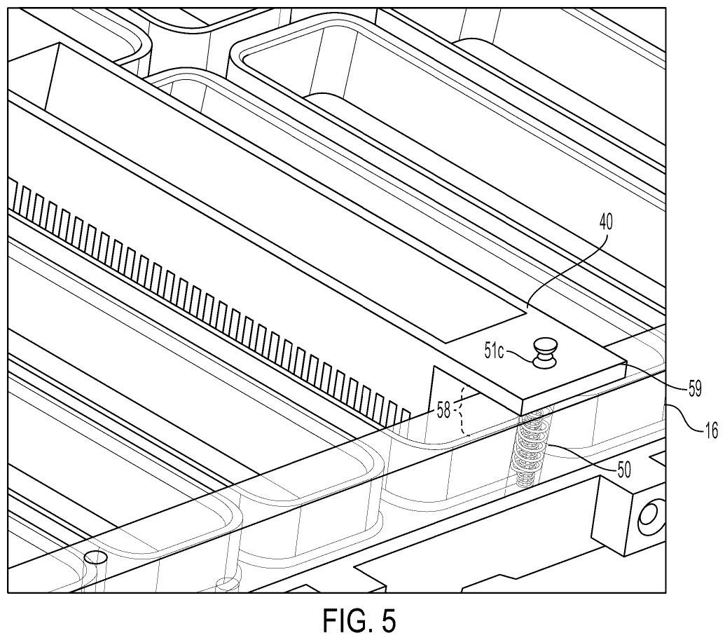

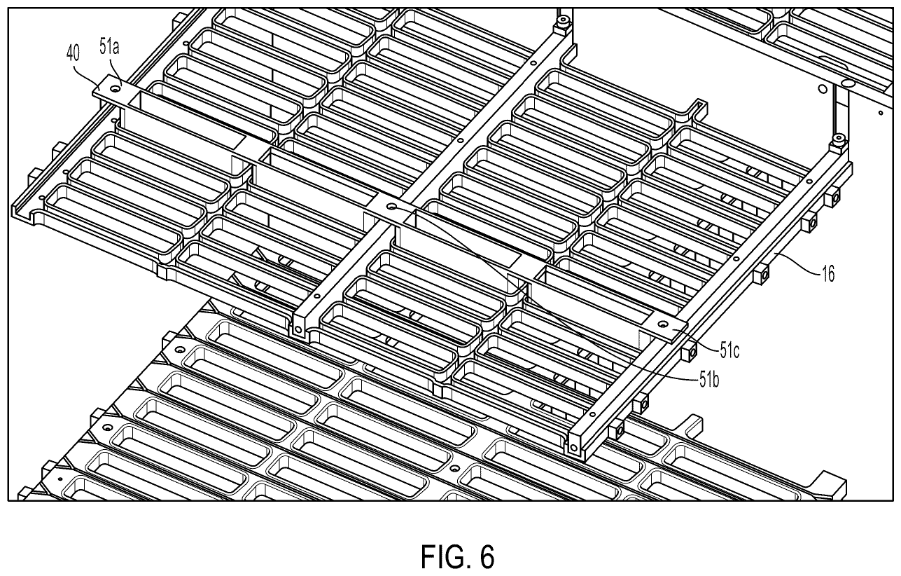

In some implementations, the stiffness adjuster is, or includes, one or more springs such as spring 50 (FIG. 5), each having a stiffness K that may, or may not, be adjustable. For example, there may be a single spring at location 51a (FIGS. 2, 5, 6) which is a first edge of frame 16, at location 51b (FIG. 6) which is a middle of frame 16, and at location 51c (FIG. 6) which is a second edge of frame 16. In some implementations, there may be two or more springs at each of locations 51a, 51b, 51c. Each spring, such as spring 50 (FIG. 5), may be fixed to both frame 16 and carrier 40 and mounted so that the carrier 40 is movable relative to frame 16 and within its openings in response to force resulting from pressure differentials, such as applied force (through pressurized air or suction).

As described below, the applied force causes the spring(s) to compress, thereby resulting in movement of the carrier 40 relative to the frame 16 and thereby exposing the carrier's holes 44 (FIG. 3) (or more of the carrier's holes 44 than are exposed absent force) allowing air to pass through those exposed holes. In this context, exposing a hole includes causing the carrier to move so that the hole is not covered by a side 16a, 16b of the frame, thereby allowing air to pass therethrough. In some implementations, the stiffness K of the spring(s) of a carrier may be adjusted based on a target impedance for a slot containing that carrier and a projected air flow for the slot.

Referring to FIGS. 5 and 6 (but particularly to FIG. 5), carrier 40 is coupled to frame 16 via spring(s) such that there is a gap 58 between the part 59 of carrier 40 to which spring 50 is attached and part of frame 16. This is the case also at locations 51a and 51b, as shown in FIG. 6. Mounting carrier 40 relative to frame 16 using the springs (or other stiffness adjusters) enables the carrier to move relative to frame 16 in response to force applied to surface 41 (FIG. 3). That is, in response to force, spring 50 (or other stiffness adjuster) compresses, thereby enabling movement of the carrier 40 relative to the frame 16. The sides 16a, 16b of frame 16 and the sides 45, 46 carrier 40 are sized, and the locations of holes 44 are placed and sized, so that movement of carrier 40 relative to frame 16 exposes the holes (which, absent force, are all or mostly blocked by the sides of frame 16). The magnitude of the force that is applied to surface 41 and the stiffness of spring 50 control how much, e.g., how far, carrier 40 moves relative to frame 16. That is, the greater the force is, the more the carrier moves and the more holes or the more of the holes that are exposed.

An example of spring 50 is a compression spring having force/deflection dependency F=K*X, which can be adjusted by its stiffness K. The following equation will be met for any operating points, i, of enclosure 12:

$$P 1 i * A 1 = P 2 i * A 2 + K * Xi ,$$

where i is a slot number; P1i is the partial pressure at any given location, i; P2i is the partial pressure at any given location, i; A1 is the area of carrier's side receiving the air flow; A2 is the area of carrier's side opposite to the side receiving the air flow; Xi is the average compression distance among the (e.g., three) springs in the carrier; and K is the springs' nominal stiffness value.

By moving the carrier in the manner described above, the holes 44 or additional holes 44 are exposed to air (e.g., no longer blocked by the frame), thereby allowing air flow through the holes. The holes therefore throttle the air flow through carrier 40 and, thus, over the PCBs within enclosure 12. The air flow is throttled to meet a target impedance of the air flow that the carrier is configured, e.g., designed, arranged, positioned, or otherwise made to produce.

By configuring the carriers, and arranging the carriers in all or some slots of one or both frames 16, 16, the distribution of air flow through the enclosure, and thus over the PCBs within the enclosure, can be more even than absent the carrier(s). For example, if all springs have the same stiffness and the volumetric air flow is greater in the center 27a of enclosure 12 than on its sides 27b, 27c, then the carrier(s) in the center of enclosure will initially move relative to the frame more than carriers at the ends of enclosure 12. However, the carrier(s) will limit air flow out of region 27 causing pressure to build in region 27 of enclosure 12. This pressure will act on each carrier in substantially the same manner (e.g., within a 20%, 10%, or less difference), eventually causing the carriers at the ends to move relative to the frame at about the same amount (e.g., within a 20%, 10%, or less difference) as the carrier(s) in the center of enclosure. In some implementations, this may cause differences in air flow through different slots in different regions to be reduced. Stated differently, in some implementations, the pressure acting on all of the carriers may cause the air flow at each region and through each carrier to be substantially the same (e.g., within a 20%, 10%, or less difference), thereby causing air flow to distribute across the PCBs more evenly than without the carriers which, in turn, may result in more even cooling of PCBs in the sockets.

Similarly the volumetric air flow across sockets that are empty may be more than the volumetric air flow across sockets that contain PCBs. The air flow through carriers associated with empty sockets may be regulated in the manner described above, resulting in more equal distribution of air flow and more equal cooling of PCBs in the sockets than would occur absent the carriers.

The examples described above are with respect to carrier 40 associated with slot 16. Each slot in one or more frames, as indicated above, may include a carrier that operates in the manner described above for carrier 40.

FIG. 7 is a block diagram showing example components of example test system that may be used to test the PCBs in enclosure 12 and to control operation of the air movers to cool the PCBs. The test system may be, or include automatic test equipment (ATE) 60. In this example, ATE 60 includes a test head 61, which may be in wired or wireless communication with enclosure 12 and, in particular, with the sockets therein.

In this example, test head 61 includes test instruments 62a to 62n (where n>3), each of which may be configured, as appropriate, to implement PCB testing as described herein and/or other functions. Although only four test instruments are shown, ATE 60 may include any appropriate number of test instruments, including one or more residing outside of test head 61. The test instruments may be hardware devices that each may include memory 64 and one or more processing devices 65 and/or other circuitry (not shown). The memory and processing devices are illustrated only on test 62n. The test instruments may be configured—for example, programmed—to generate test signals to send to the PCBs in enclosure 12 via the sockets, to receive response signals from the PCBs that are based on the test signals, and to determine whether a PCB passed or failed testing based on the response signals. The test instruments may include other test electronics as well, such as pin electronics and/or one or more parametric measurement units (PMUs).

The test instruments may be configured to control operation of the fans or other coolant movers to generate a volumetric coolant flow during testing to cool the PCBs. For example, there may be a temperature sensor (not shown) in enclosure that communicates with one or more test instruments 62a to 62n. The reading(s) from that temperature sensor may cause the test instrument to increase or to decrease the volumetric coolant flow by controlling operations of the coolant movers to increase or to decrease the flow of coolant.

Communications between the test instruments 62a to 62n and an enclosure, such as enclosure 12, may be over one or more test channels 66. The test channels may include wired and/or wireless communication media.

In some implementations, control signals to implement the controls described herein may be generated by test program(s) executing on one or more of the test instruments and/or on the control system described below.

Control system 68 may be configured—e.g., programmed—to communicate with test instruments 62a to 62n to direct and/or to control testing of DUTs, such as, but not limited to, controlling the operations of the fans. In some implementations, this communication 69 may be over a computer network or via a direct connection such as a computer bus or an optical medium. In some implementations, the computer network may be or include a local area network (LAN) or a wide area network (WAN).

The control system may be or include a computing system comprised of one or more processing devices 70 (e.g., microprocessor(s)) and memory 71 for storing machine-executable instructions 72 to execute to control operation of the ATE and/or testing, and/or one or more test programs to execute and/or to send to the test instruments for execution. Control system 68 may also be configured to receive and to process and/or analyze response signals.

In some implementations, the control functionality of the control system is centralized in processing device(s) 70. In some implementations, all or part of the control functionality attributed to control system 68 may also or instead be implemented on one or more test instruments and/or all or part of the testing functionality attributed to one or more test instruments may also or instead be implemented on control system 68. For example, the control system may be distributed across processing device(s) 65 and one or more of test instruments 62a to 62n

All or part of the systems and processes described herein may be configured and/or controlled at least in part by one or more computers using one or more computer programs tangibly embodied in one or more information carriers, such as in one or more non-transitory machine-readable storage media. A computer program can be written in any form of programming language, including compiled or interpreted languages, and it can be deployed in any form, including as a stand-alone program or as a module, part, subroutine, or other unit suitable for use in a computing environment. A computer program can be deployed to be executed on one computer or on multiple computers at one site or distributed across multiple sites and interconnected.

Actions associated with configuring or controlling the test system and processes described herein can be performed by one or more programmable processors executing one or more computer programs to control or to perform all or some of the operations described herein. All or part of the test systems and processes can be configured or controlled by special purpose logic circuitry, such as, an FPGA (field programmable gate array) and/or an ASIC (application-specific integrated circuit) or embedded microprocessor(s) localized to the instrument hardware.

Processors suitable for the execution of a computer program include, by way of example, both general and special purpose microprocessors, and any one or more processors of any kind of digital computer. Generally, a processor will receive instructions and data from a read-only storage area or a random access storage area or both. Elements of a computer include one or more processors for executing instructions and one or more storage area devices for storing instructions and data. Generally, a computer will also include, or be operatively coupled to receive data from, or transfer data to, or both, one or more machine-readable storage media, such as mass storage devices for storing data, such as magnetic, magneto-optical disks, or optical disks. Non-transitory machine-readable storage media suitable for embodying computer program instructions and data include all forms of non-volatile storage area, including by way of example, semiconductor storage area devices, such as EPROM (erasable programmable read-only memory), EEPROM (electrically erasable programmable read-only memory), and flash storage area devices; magnetic disks, such as internal hard disks or removable disks; magneto-optical disks; and CD-ROM (compact disc read-only memory) and DVD-ROM (digital versatile disc read-only memory).

As used herein, the terms “comprises,” “comprising,” “includes,” “including,” “has,” “having,” “contains,” “containing,” and any variations thereof, are intended to cover a non-exclusive inclusion, such that systems, techniques, apparatus, structures, processes, or other subject matter described or claimed herein that includes, has, or contains an element or list of elements does not include only those elements but can include other elements not expressly listed or inherent to such systems, techniques, apparatus, structures, processes or other subject matter described or claimed herein.

All examples described herein are non-limiting.

In the description and claims provided herein, the adjectives “first”, “second”, “third”, and the like do not designate priority or order unless context suggests otherwise. Instead, these adjectives may be used solely to differentiate the nouns that they modify.

Any mechanical or electrical connection herein may include a direct physical connection or an indirect physical connection that includes one or more intervening devices unless context suggests otherwise. A connection between two electrically conductive devices includes an electrical connection unless context suggests otherwise. The signals described herein are electrical signals unless context suggests otherwise.

Elements of different implementations described may be combined to form other implementations not specifically set forth previously. Elements may be left out of the systems described previously without adversely affecting their operation or the operation of the system in general. Furthermore, various separate elements may be combined into one or more individual elements to perform the functions described in this specification.

Other implementations not specifically described in this specification are also within the scope of the following claims.

What is claimed is:

1. A system comprising:
a structure comprising a slot;
a carrier comprising a surface arranged to receive a flow of coolant, the carrier comprising holes to allow coolant to pass therethrough, the holes being on a part of the carrier other than the surface, where at least part of the carrier, including the surface, is within the slot; and
a stiffness adjuster between a part of the carrier and a part of the structure, the stiffness adjuster having a stiffness that is based on a target impedance of coolant flow through the slot.

2. The system of claim 1, wherein, at least one of a size, a shape, a number, or locations of the holes is based on the target impedance of the flow of coolant through the slot.

3. The system of claim 1, further comprising:
an enclosure containing the structure, the enclosure comprising a coolant inlet and a coolant outlet that together enable a coolant flow path through the enclosure, the carrier being arranged in the coolant flow path such that the flow of coolant extends to and through the holes of the carrier.

4. The system of claim 3, wherein the stiffness adjuster comprises a spring; and
wherein the carrier is mounted such that force resulting from the flow of coolant at the surface of the carrier causes the carrier to move within the slot, where an amount of movement of the carrier within the slot is based on the stiffness of the spring.

5. The system of claim 4, further comprising multiple springs between respective parts of the carrier and respective parts of the structure, the spring being among the multiple springs, the multiple springs having stiffnesses that are based on the target impedance of the flow of coolant through the slot.

6. The system of claim 5, wherein the carrier comprises multiple surfaces including the surface, each of the multiple surfaces having a respective set of sides extending therefrom, each respective set of sides comprising holes to allow coolant to pass therethrough, the slot comprising multiple openings, each opening holding a corresponding surface of the carrier.

7. The system of claim 6, wherein the force resulting from the flow of coolant at surfaces of the carrier causes the carrier to move within the slot, where an amount of movement of the carrier within the slot is based on the stiffnesses of the multiple springs.

8. The system of claim 7, further comprising:
an electrical connector associated with the slot, the electrical connector being configured to hold an electronic device to be tested.

9. The system of claim 5, wherein the enclosure further comprises:
one or more coolant movers to produce the coolant flow.

10. The system of claim 6, wherein the one or more coolant movers comprise one or more fans located at the coolant outlet.

11. The system of claim 1, wherein the structure comprises multiple slots;
wherein the system comprises multiple carriers including the carrier, each respective carrier of the multiple carriers comprising a respective surface comprising holes to allow a respective flow of coolant to pass therethrough, at least part of each respective carrier including a respective surface thereof being within a respective slot of the multiple slots; and
wherein the stiffness adjuster comprises a spring and the system comprises multiple springs including the spring, each of the multiple springs being between a part of a respective carrier and a part of the structure, each spring having a stiffness that is based on a target impedance of the flow of coolant through the respective slot.

12. The system of claim 11, wherein different ones of the multiple slots have different target impedances for the flow of coolant.

13. The system of claim 11, wherein the stiffness of each spring is configured so that differences between flows of coolant through the multiple slots are reduced.

14. The system of claim 11, further comprising:
electrical connectors associated respective slots of the multiple slots, each electrical connector for holding an electronic device to be tested.

15. The system of claim 14, further comprising:
test electronics to test the electronic device in each slot.

16. A system comprising:
multiple carriers, each of the multiple carriers comprising holes to allow coolant to pass therethrough;
a frame comprising multiple slots, each of the multiple slots comprising openings for holding a respective one of the multiple carriers such that the respective one of the multiple carriers is movable within the slot; and
springs between each of the multiple carriers and the frame, each spring having a stiffness that affects movement of a respective carrier within a respective slot in response to coolant flow contacting the respective carrier;
wherein each spring is arranged relative to the frame and the multiple carriers so that differences between coolant flow through the multiple slots are reduced.

17. The system of claim 16, further comprising:
electrical connectors associated with respective slots, each electrical connector for holding an electronic device to be tested within a coolant flow path.

18. The system of claim 16, wherein, at least one of a size, a shape, a number, or locations of the holes in each carrier is based on the target impedance of coolant flow through each slot.

19. The system of claim 16, wherein each carrier has a rectangular shape in cross-section with one end of the rectangular shape open.

20. The system of claim 16, which is part of automatic test equipment.
